(19) United States
(12) Patent Application Publication
(10) Pub. No.: US 2006/0249734 A1
(43) Pub. Date: Nov. 9, 2006

(54) Image display device and method of manufacturing the same

(76) Inventors: Nobuyuki Aoyama, Fukaya-shi (JP); Masaru Nikaido, Ibo-gun (JP); Satoshi Ishikawa, Fukaya-shi (JP); Satoko Oyaizu, Fukaya-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/480,849

(22) Filed: Jul. 6, 2006

Related U.S. Application Data
(63) Continuation of application No. PCT/JP04/19037, filed on Dec. 20, 2004.

(30) Foreign Application Priority Data
Jan. 6, 2004 (JP) 2004-001050

(51) Int. Cl. H01L 21/00; H01L 29/04

(52) U.S. Cl. 257/72; 438/34

(57) ABSTRACT

A first substrate having an image display screen formed thereon is located opposite a second substrate provided with a plurality of electron emitting sources. A plurality of spacers are provided between the first substrate and the second substrate, and support an atmospheric load which acts on the first and second substrates. Each of the spacers is formed of at least two types of materials with different softening temperatures, and end portions which abut against at least one of the first substrate and the second substrate are formed of a material with a high softening temperature.

### CROSS REFERENCE TO RELATED APPLICATIONS

This is a Continuation Application of PCT Application No. PCT/JP2004/019037, filed Dec. 20, 2004, which was published under PCT Article 21(2) in Japanese.

This application is based upon and claims the benefit of priority from prior Japanese Patent Application No. 2004-001050, filed Jan. 6, 2004, the entire contents of which are incorporated herein by reference.

### BACKGROUND OF THE INVENTION

1. Field of the Invention

This invention relates to an image display device, having substrates located opposite each other and a plurality of spacers arranged between the substrates, and a method of manufacturing the same.

2. Description of the Related Art

In recent years, various flat image display devices have come to attention as the next generation of lightweight, thin display devices to replace cathode-ray tubes (hereinafter, referred to as CRTs). For example, a surface-conduction electron emission device (hereinafter, referred to as an SED) has been developed as a kind of a field emission device (hereinafter, referred to as an FED) that serves as a flat display device.

This SED comprises a first substrate and a second substrate that are located opposite each other with a predetermined gap between them. These substrates have their respective peripheral portions joined together by a rectangular sidewall, thereby constituting a vacuum envelope. Three color phosphor layers are formed on the inner surface of the first substrate. Arranged on the inner surface of the second substrate are a large number of electron emitting elements for use as electron sources, which correspond to pixels, individually, and excite the phosphors. Each electron emitting element is composed of an electron emitting portion, a pair of electrodes that apply voltage to the electron emitting portion, etc.

For the SED described above, it is important to maintain a high degree of vacuum in a space between the first substrate and the second substrate, that is, in the vacuum envelope. If the degree of vacuum is low, the life of the electron emitting elements, and hence, the life of the device shorten inevitably. In an arrangement described in Jpn. Pat. Appln. KOKAI Publication No. 2001-272926, for example, a large number of plate-shaped or columnar spacers are located between a first substrate and a second substrate in order to support an atmospheric load that acts between the two substrates and maintain a gap between the substrates (e.g., Patent Document 1). In displaying an image in the SED, anode voltages are applied to the phosphor layers, and electron beams emitted from the electron emitting elements are accelerated by the anode voltages and collided with the phosphor layers, whereupon the phosphors glow and display the image. In order to obtain practical display properties, it is necessary to use phosphor layers similar to those of conventional cathode-ray tubes and set the anode voltages to several kV, preferably 5 kV or more.

In the flat image display device described above, a high voltage of 5 kV is applied between a front plate and a rear plate, whereby electrons emitted from the electron emitting elements arranged on the rear plate are accelerated to reach the phosphors the front plate. Since the luminance of the displayed image depends on the accelerated voltage, the voltage should preferably be a high voltage (high withstand voltage). In view of the resolution, properties of supporting members, manufacturability, etc., however, the gap between the first substrate and the second substrate is set to a relatively small amount of about 1 to 2 mm. If a high voltage is applied, therefore, a strong electric field is inevitably formed in the gap between the first substrate and the second substrate, so that electric discharge (dielectric breakdown) easily occurs between the two substrates. If the electric discharge occurs, the electron emitting elements, a fluorescent surface, and a driver circuit may possibly be broken or degraded. The electric discharge that results in such failure is not allowable for the device as a product.

In order to maintain a high voltage without entailing electric discharge, it is necessary to reduce the gap between the first substrate or the second substrate and spacers and clear the space between the first substrate and the second substrate of floating dust. Since a large number of spacers are provided between the first substrate and the second substrate, however, it is difficult to make all the spacers uniform in height and remove the gap between each substrate and the spacers. After the large number of spacers are formed, moreover, an attempt may be made to polish them simultaneously for uniformity in height. In this case, however, it is hard to remove dust thoroughly.

### BRIEF SUMMARY OF THE INVENTION

This invention has been made in consideration of these circumstances, and its object is to provide an image display device with improved reliability and display quality, in which electric discharge is restrained from occurring between first and second substrates, and a method of manufacturing the same.

According to an aspect of the invention, there is provided an image display device comprising: a first substrate having an image display screen formed thereon; a second substrate located opposite the first substrate with a predetermined gap therebetween and provided with a plurality of electron emitting sources which excite the image display screen; and a plurality of spacers which are individually formed of dielectric materials, are provided between the first substrate and the second substrate, individually have end portions which abut against at least one of the first substrate and the second substrate, and support an atmospheric load which acts on the first and second substrates, each of the spacers being formed of at least two types of materials with different softening temperatures, the end portions which abut against at least one of the first substrate and the second substrate being formed of a material with a high softening temperature.

According to another aspect of the invention, there is provided an image display device comprising: a first substrate having an image display screen formed thereon; a second substrate located opposite the first substrate with a predetermined gap therebetween and provided with a plurality of electron emitting sources which excite the image display screen; a plate-shaped supporting substrate having a plurality of electron beam apertures opposed individually to the electron emitting elements and provided opposite the first and second substrates and between the first and second substrates; and a plurality of spacers which are individually formed of dielectric materials, are provided on the supporting substrate, individually have end portions which abut against at least one of the first substrate and the second substrate, and support an atmospheric load which acts on the first and second substrates, each of the spacers being formed of at least two types of materials with different softening temperatures, the end portions which abut against at least one of the first substrate and the second substrate being formed of a material with a high softening temperature.

According to an aspect of the invention, there is provided a method of manufacturing an image display device which comprises a first substrate having an image display screen formed thereon, a second substrate located opposite the first substrate with a predetermined gap therebetween and provided with a plurality of electron emitting sources which excite the image display screen, and a plurality of spacers which are individually formed of dielectric materials, are provided between the first substrate and the second substrate, individually have end portions which abut against at least one of the first substrate and the second substrate, and support an atmospheric load which acts on the first and second substrates, the method comprising:

preparing a molding die having a plurality of bottomed spacer forming holes; filling a bottom portion of each spacer forming hole of the molding die with an amount of a first material which contains glass and has a high softening temperature, the amount being smaller than the size of the spacer forming hole; filling each spacer forming hole of the molding die, filled with the first material, with a second material which contains glass and has a softening temperature lower than the softening temperature of the first material; curing and then releasing the loaded first and second materials from the molding die; firing the released first and second materials to form the plurality of spacers; and pressing the plurality of fired spacers in a height direction thereof to mold the spacers to a common height by means of a pressure plate which engages respective distal ends of the plurality of spacers when the plurality of spacers are heated to a temperature lower than the softening temperature of the first material and not lower than the softening temperature of the second material.

According to another aspect of the invention, there is provided a method of manufacturing an image display device which comprises a first substrate having an image display screen formed thereon, a second substrate located opposite the first substrate with a predetermined gap therebetween and provided with a plurality of electron emitting sources which excite the image display screen, a plate-shaped supporting substrate having a plurality of electron beam apertures opposed individually to the electron emitting elements and provided opposite the first and second substrates and between the first and second substrates, and a plurality of spacers which are individually formed of dielectric materials, are provided on the supporting substrate, individually have end portions which abut against the first substrate and/or the second substrate, and support an atmospheric load which acts on the first and second substrates, the method comprising:

preparing a plate-shaped supporting substrate having a plurality of electron beam apertures and a molding die having a plurality of bottomed spacer forming holes; filling a bottom portion of each spacer forming hole of the molding die with an amount of a first material which contains glass and has a high softening temperature, the amount being smaller than the size of the spacer forming hole; filling each spacer forming hole of the molding die, filled with the first forming material, with a second material which contains glass and has a softening temperature lower than the softening temperature of the first material; curing and then releasing the loaded first and second materials from the molding die and locating the materials on the supporting substrate with the second material side bonded to the supporting substrate; firing the first and second materials on the supporting substrate to form the plurality of spacers; and pressing the plurality of fired spacers in a height direction thereof to mold the spacers to a common height by means of a pressure plate which engages respective distal ends of the plurality of spacers when the plurality of spacers are heated to a temperature lower than the softening temperature of the first material and not lower than the softening temperature of the second material.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing an SED according to a first embodiment of this invention;

FIG. 2 is a perspective view of the SED cut away along line II-II of FIG. 1;

FIG. 3 is a sectional view enlargedly showing the SED;

FIG. 4 is a sectional view enlargedly showing a part of a spacer structure of the SED;

FIG. 5 is a sectional view showing a grid and molding dies used in the manufacture of the spacer structure;

FIG. 6A is a sectional view enlargedly showing the molding die;

FIG. 6B is a sectional view enlargedly showing the molding die;

FIG. 7 is a sectional view showing a process for UV irradiation with the molding dies filled with a first material and a second material;

FIG. 8 is a sectional view showing an assembly in which the molding dies and the grid are in close contact with one another;

FIG. 9 is a sectional view showing a state in which the molding dies are separated;

FIG. 10 is a sectional view showing a pressing process for the spacer structure;

FIG. 11 is a sectional view enlargedly showing a part of an SED according to a second embodiment of this invention;

FIG. 12A is a sectional view showing a state in which the molding die is filled with the second material in the second embodiment;

FIG. 12B is a sectional view showing a state in which the molding die is filled with the second material in the second embodiment;

FIG. 13 is a sectional view showing an assembly in which the molding dies and a grid are in close contact with one another in the second embodiment;

FIG. 14 is a sectional view showing a process for spraying the first material to the grid and the second material in the second embodiment;

FIG. 15 is a sectional view showing a pressing process for a spacer structure in the second embodiment;

FIG. 16 is a sectional view enlargedly showing a part of an SED according to a third embodiment of this invention;

FIG. 17A is a sectional view showing a state in which the molding die is filled with a spacer forming material in the third embodiment;

FIG. 17B is a sectional view showing a state in which the molding die is filled with the spacer forming material in the third embodiment;

FIG. 18 is a sectional view showing an assembly in which the molding dies and a grid are in close contact with one another in the third embodiment;

FIG. 19 is a sectional view showing a pressing process for a spacer structure in the third embodiment; and

FIG. 20 is a sectional view enlargedly showing an SED according to a fourth embodiment of this invention.

### DETAILED DESCRIPTION OF THE INVENTION

Embodiments in which this invention is applied to an SED, a kind of FED as a flat image display device, will now be described in detail with reference to the drawings.

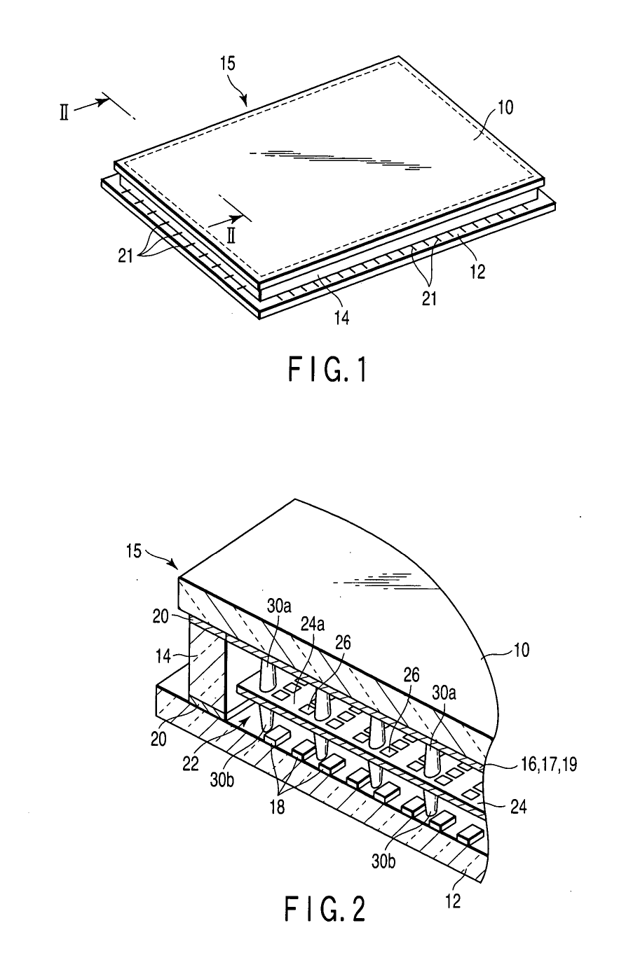

As shown in FIGS. 1 to 3, the SED comprises a first substrate 10 and a second substrate 12, which are formed of a rectangular glass substrate each. These substrates are located opposite each other with a gap of about 1.0 to 2.0 mm between them. The first substrate 10 and the second substrate 12 have their respective peripheral edge portions joined together by a sidewall 14 of glass in the form of a rectangular frame, thereby forming a flat vacuum envelope 15 the inside of which is kept vacuum.

A phosphor screen 16 that functions as an image display screen is formed on the inner surface of the first substrate 10. The phosphor screen 16 is formed by arranging phosphor layers R, G and B, which glow red, green, and blue, respectively, and light shielding layers 11 side by side. Each of these phosphor layers is stripe-shaped, dot-shaped, or rectangular. A metal back 17 of aluminum or the like and a getter film 19 are successively formed on the phosphor screen 16.

Provided on the inner surface of the second substrate 12 are a large number of surface-conduction electron emitting elements 18, which individually emit electron beams as electron emission sources for exciting the phosphor layers R, G and B of the phosphor screen 16. These electron emitting elements 18 are arranged in a plurality of columns and a plurality of rows corresponding to one another for each pixel. Each electron emitting element 18 is formed of an electron emitting portion (not shown), element electrodes that apply voltage to the electron emitting portion, etc. A large number of wires 21 that supply potential to the electron emitting elements 18 are provided in a matrix on the inner surface of the second substrate 12, and their respective end portions are drawn out of the vacuum envelope 15.

The sidewall 14 that functions as a joint member is sealed to the peripheral edge portion of the first substrate 10 and the peripheral edge portion of the second substrate 12 by a sealing material 20, such as low-melting-point glass or low-melting-point metal, thereby joining these substrates together.

As shown in FIGS. 2 and 4, the SED comprises a spacer assembly 22 located between the first substrate 10 and the second substrate 12. In the present embodiment, the spacer assembly 22 comprises a grid 24 formed of a rectangular metallic plate located between the first and second substrates 10 and 12 and a large number of columnar spacers set up integrally on the opposite surfaces of the grid.

More specifically, the grid 24 that functions as a supporting substrate has a first surface 24a opposed to the inner surface of the first substrate 10 and a second surface 24b opposed to the inner surface of the second substrate 12, and is located parallel to these substrates. A large number of electron beam apertures 26 are formed in the grid 24 by etching or the like. The electron beam apertures 26 are arranged opposite the electron emitting elements 18, individually, and electron beams emitted from the electron emitting elements are transmitted through them.

The grid 24 is formed of, for example, an iron-nickel-based metallic plate of thickness 0.1 to 0.3 mm. Formed on the surface of the grid 24 is an oxide film of elements that constitute the metallic plate, e.g., an oxide film of Fe₃O₄ and NiFe₂O₄. The surfaces 24a and 24b of the grid 24 and the respective wall surfaces of the electron beam apertures 26 are covered by a high-resistance film that has a discharge current limiting effect. This high-resistance film is formed of a high-resistance material that consists mainly of glass.

A plurality of first spacers 30a are set up integrally on the first surface 24a of the grid 24 and situated individually between the adjacent electron beam apertures 26. The respective distal ends of the first spacers 30a abut against the inner surface of the first substrate 10 through the getter film 19, the metal back 17, and the light shielding layers 11 of the phosphor screen 16.

A plurality of second spacers 30b are set up integrally on the second surface 24b of the grid 24 and situated individually between the adjacent electron beam apertures 26. The respective distal ends of the second spacers 30b abut against the inner surface of the second substrate 12. Here the distal ends of the second spacers 30b are situated on the wires 21 on the inner surface of the second substrate 12. The first and second spacers 30a and 30b are situated in alignment with one another and formed integrally with the grid 24 so as to hold the grid 24 between them from both sides.

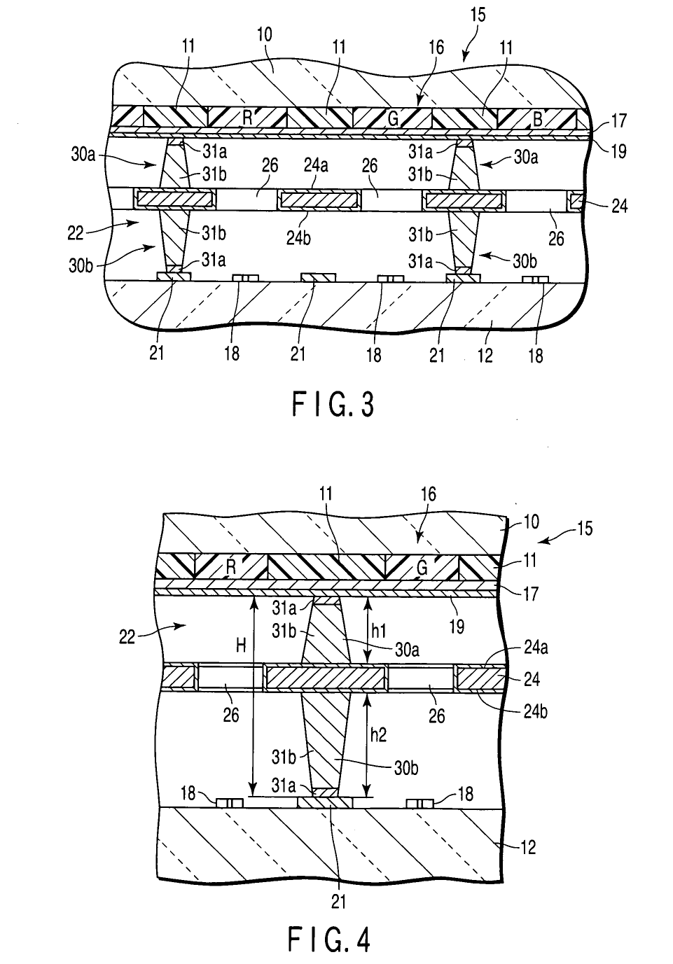

As shown in FIGS. 3 and 4, each of the first and second spacers 30a and 30b is tapered so that its diameter is reduced from the side of the grid 24 toward its extended end. For example, each first spacer 30a has a substantially elliptic cross-sectional shape such that the diameters of its proximal end on the side of the grid 24 measure about 0.3 mm by 2 mm, the diameters of its extended end measure about 0.2 mm by 2 mm, and its height h1 in the direction perpendicular to the first and second substrates 10 and 12 is about 0.8 mm. An overall height H of the spacer structure 22 including the grid 24 is 1.52 mm.

Height differences between the adjacent first spacers 30a are restricted within 5 μm, and height variation of all the first spacers is restricted within 0.1 mm. Further, height differences between the adjacent second spacers 30b are restricted within 5 μm, and height variation of all the second spacers is restricted within 0.1 mm.

Each of the first and second spacers 30a and 30b is formed of at least two types of materials with different softening temperatures. In this case, a tip portion 31a of each first spacer 30a that abuts against the first substrate 10 is formed of a first material with a high softening temperature, while the other portion or a base portion 31b thereof is formed of a second material with a softening temperature lower than that of the first material. Likewise, a tip portion 31a of each second spacer 30b that abuts against the second substrate 12 is formed of the first material with a high softening temperature, while a base portion 31b thereof is formed of the second material with a softening temperature lower than that of the first material. Materials that contain glass as a dielectric substance are used for the first and second materials.

The spacer structure 22 constructed in this manner is located between the first substrate 10 and the second substrate 12. The first and second spacers 30a and 30b abut against the respective inner surfaces of the first substrate 10 and the second substrate 12, thereby supporting an atmospheric load that acts on these substrates and keeping a space between the substrates at a given value.

The SED is provided with a voltage supply section (not shown) that applies voltage to the grid 24 and the metal back 17 of the first substrate 10. This voltage supply section is connected to the grid 24 and the metal back 17 and supplies voltages of, for example, 12 kV and 10 kV to the grid 24 and the metal back 17, respectively. In displaying an image in the SED, anode voltages are applied to the phosphor screen 16 and the metal back 17, and electron beams emitted from the electron emitting elements 18 are accelerated by the anode voltages and collided with the phosphor screen 16. Thus, the phosphor layers of the phosphor screen 16 are excited to fluoresce, whereupon the image is displayed.

The following is a description of a manufacturing method for the SED constructed in this manner. A method of manufacturing the spacer structure 22 will be described first.

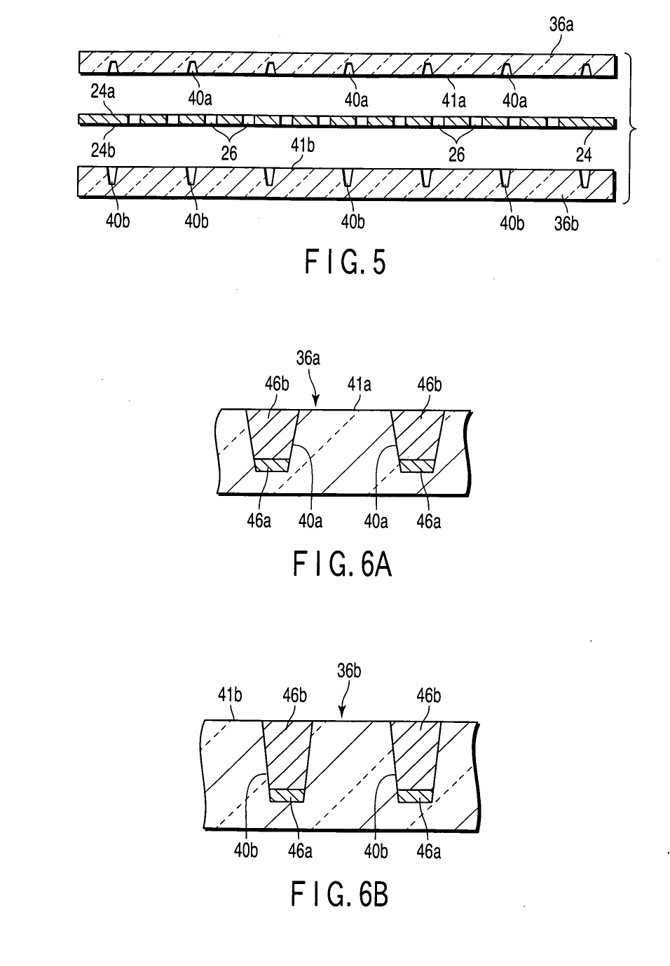

As shown in FIG. 5, the grid 24 having a given size and upper and lower dies 36a and 36b, each in the form of a rectangular plate having substantially the same size as the grid, are prepared first. After a metal plate of Fe-50% Ni with a plate thickness of 0.12 mm is degreased, cleaned, and dried, in this case, the electron beam apertures 26 are formed by etching. After the entire metal plate is oxidized, thereafter, a dielectric film is formed on the grid surface including the respective inner surfaces of the electron beam apertures 26. Further, a high-resistance film is formed by applying a glass-based coating liquid to the dielectric film, drying it, and then firing it. The grid 24 is obtained by doing this.

The upper die 36a and the lower die 36b for use as molding dies are flat plates that are formed of a transparent material that is permeable to ultraviolet rays, such as clear silicone or clear polyethylene terephthalate. The upper die 36a has a flat contact surface 41a to be in contact with the grid 24 and a large number of bottomed spacer forming holes 40a for molding the first spacers 30a. The spacer forming holes 40a individually open in the contact surface 41a of the upper die 36a and are arranged at predetermined intervals. Likewise, the lower die 36b has a flat contact surface 41b and a large number of bottomed spacer forming holes 40b for molding the second spacers 30b. The spacer forming holes 40b individually open in the contact surface 41b of the lower die 36b and are arranged at predetermined intervals.

Subsequently, the spacer forming holes 40a of the upper die 36a and the spacer forming holes 40b of the lower die 26b are filled with spacer forming materials. Two types of materials, a first material 46a and a second material 46b with different softening temperatures, are used as the spacer forming materials. A glass paste that contains at least an ultraviolet-curing binder (organic component) and a glass filler and has a softening temperature of 585° C. and a firing temperature of 580° C.×30 minutes is used as the first material 46a. A glass paste that contains at least an ultraviolet-curing binder (organic component) and a glass filler and has a softening temperature of 550° C. and a firing temperature of 550° C.×30 minutes is used as the second material 46b. The specific gravity and viscosity of each glass paste are selected suitably.

As shown in FIGS. 6A and 6B, the first material 46a of an amount equal to about 20% of the size of each spacer forming hole 40a of the upper die 36a is loaded into the bottom part of the spacer forming hole 40a. Subsequently, the second material 46b is loaded into the spacer forming holes 40a to fill the spacer forming holes 40a. Likewise, the second material 46b of an amount equal to about 20% of the size of each spacer forming hole 40b of the lower die 36b is loaded into the bottom part of the spacer forming hole 40b. Subsequently, the second material 46b is loaded into the spacer forming holes 40b to fill the spacer forming holes 40b.

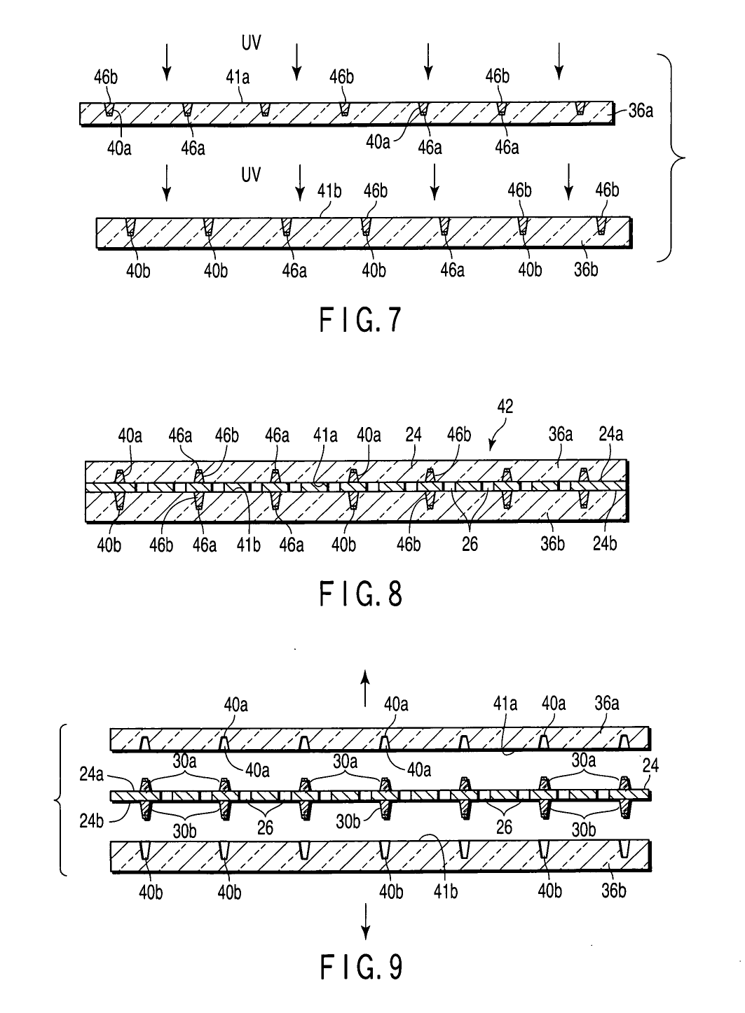

Then, as shown in FIG. 7, ultraviolet (UV) rays are applied to the first and second materials 46a and 46b from both sides of the upper die 36a and the lower die 36b to cure them by using an ultraviolet lamp, for example. In this case, the upper die 36a and the lower die 36b are individually formed of an ultraviolet transmitting material. Thus, ultraviolet rays irradiated from the ultraviolet lamp are transmitted through the upper die 36a and the lower die 36b and applied to the loaded first and second materials 46a and 46b directly and through the dies. By doing this, the first and second materials 46a and 46b are ultraviolet-cured to form the first and second spacers 30a and 30b.

Subsequently, an adhesive is applied to the respective proximal end faces of the first and second spacers, which are exposed on the contact surfaces 41a and 41b of the upper die 36a and the lower die 36b, respectively, and spacer setting positions on the grid 24 by means of a dispenser or by printing. As shown in FIG. 8, thereafter, the upper die 36a is positioned so that the cured first spacers 30a individually face regions between the electron beam apertures 26, and the contact surface 41a is brought into close contact with the first surface 24a of the grid 24. Likewise, the lower die 36b is positioned so that the second spacers 30b individually face the regions between the electron beam apertures 26, and the contact surface 41b is brought into close contact with the second surface 24b of the grid 24. By doing this, an assembly 42 is formed comprising the grid 24, upper die 36a, and lower die 36b. In the assembly 42, the spacer forming holes 40a of the upper die 36a and the spacer forming holes 40b of the lower die 36b are arranged opposite one another with the grid 24 between them.

The upper die 36a and the lower die 36b are brought into close contact with the grid 24 by pressing the assembly 42 from both surface sides. By doing this, the cured first and second spacers 36a and 36b are bonded individually to the first and second surfaces 24a and 24b of the grid 24.

As shown in FIG. 9, thereafter, the upper die 36a and the lower die 36b are separated from the grid 24 so as to leave the cured first and second spacers 30a and 30b on the grid 24. After the grid 24 having the first and second spacers 30a and 30b thereon is then heat-treated in a heating furnace so that the binder is evaporated from the first and second materials 46a and 46b, it is regularly fired at 580° C. for 30 minutes.

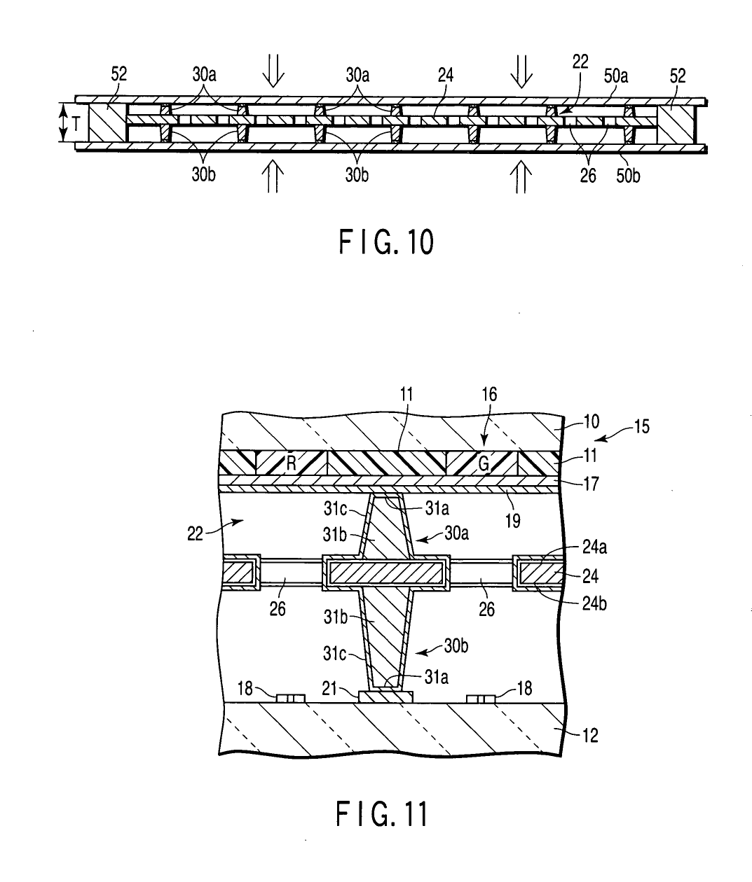

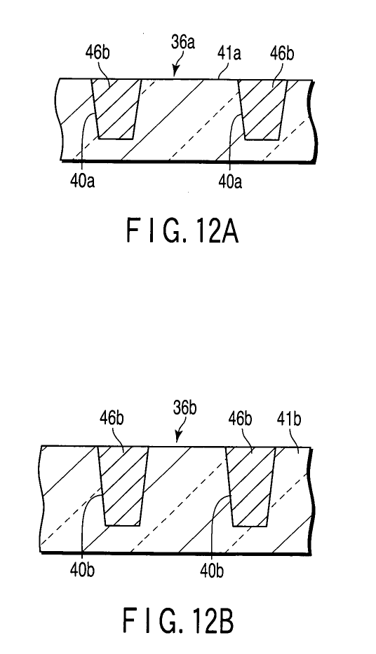

Subsequently, two flat pressure plates 50a and 50b are prepared, as shown in FIG. 10. The pressure plates 50a and 50b have an area larger than that of the grid 24 and are formed of a material having a thermal expansion coefficient substantially equal to a thermal expansion coefficient α of the grid 24. In this case, a glass plate with a plate thickness of 8 mm and α=8×10⁻⁶/° C., for example, is selected for the pressure plates 50a and 50b.

Then, the first and second spacers 30a and 30b that are set up on the grid 24 are interposed between the two pressure plates 50a and 50b so that the distal ends of the first spacers 30a are caused to abut against the pressure plate 50a and the distal ends of the second spacers 30b against the pressure plate 50b. Outside the grid 24, a plurality of gap regulating members 52 are arranged between the respective peripheral edge portions of the pressure plates 50a and 50b. A thickness T of each gap regulating member 52 is adjusted highly accurately to a target height of the spacers. The thickness T of the gap regulating member 52 is supposed to be equal to a height obtained by subtracting a compression margin from a height H that is equal to the sum of the thickness of the grid 24 and the height of each pair of first and second spacers 30a and 30b. For example, the compression margin and T are supposed to be 0.02 and 1.5 mm, respectively.

Thereafter, the first and second spacers 30a and 30b are heated to a temperature of, e.g., 550° C., which is lower than the softening temperature of the first material 46a and not lower than the softening temperature of the second material 46b, whereby only the second material 46b is softened. In this state, the pressure plates 50a and 50b are pressed toward each other and against the gap regulating members 52. Further, the first and second spacers 30a and 30b are compressed along their height direction from both sides so that they are plastically deformed to a uniform height. The height of each of the first and second spacers 30a and 30b after the compression is controlled by the gap regulating members 52. Thus, the plurality of first spacers 30a are molded to a common height, and at the same time, the plurality of second spacers 30b are molded to a common height.

Subsequently, the first and second spacers 30a and 30b are cooled to be cured again, and thereafter, the pressure plates 50a and 50b are removed. In the pressing process described above, only the second material 46b is softened, and the first material 46a that forms the respective distal end portions of the first and second spacers, which abut against the pressure plates 50a and 50b, is not softened. Accordingly, there is no possibility of the spacer end portions and the pressure plates 50a and 50b being bonded together, so that the pressure plates 50a and 50b can be easily separated without damaging the first and second spacers.

By the processes described above, the spacer structure 22 is obtained having the first and second spacers 30a and 30b built-in on the grid 24. The height differences between the adjacent first spacers 30a are restricted within 5 μm, and the height variation of all the first spacers is restricted within 0.1 mm. The height differences between the adjacent second spacers 30b are restricted within 5 μm, and the height variation of all the second spacers is restricted within 0.1 mm. In a spacer structure that is not subjected to the aforesaid pressing process, the standard deviation of the heights of the first and second spacers is 0.008. In the present embodiment, however, the standard deviation is 0.001, which indicates a considerable reduction in the spacer height variation.

In the manufacture of the SED, on the other hand, the first substrate 10, which is provided with the phosphor screen 16 and the metal back 17, and the second substrate 12, which is provided with the electron emitting elements 18 and the wires 21 and to which the sidewall 14 is bonded, are prepared in advance. Subsequently, the spacer structure 22 obtained in the aforesaid manner is positioned on the second substrate 12. In this state, the first substrate 10, second substrate 12, and spacer structure 22 are located in a vacuum chamber, the vacuum chamber is evacuated, and thereafter, the first substrate is bonded to the second substrate with the sidewall 14 between them. By doing this, the SED is manufactured having the spacer structure 22.

The SED constructed in this manner and an SED having dispensed with the spacer height variation control were prepared, and a discharge test was conducted for each of them. When the SED not controlled for height variation was held at an acceleration voltage of 10 kV for one hour, electric discharge occurred about 10 times. When this SED was held for 10 hours, electric discharge occurred about 25 times. For the SED according to the present embodiment, on the other hand, no electric discharge occurred under the same conditions.

According to the SED constructed in this manner and its manufacturing method, the height variation of the first spacers 30a and the second spacers 30b can be eliminated, and the gaps between the first substrate and the first spacers and between the second substrate and the second spacers can be reduced considerably. Accordingly, there may be obtained an SED with high dielectric strength and improved reliability in which electric discharge can be restrained from being caused by the gaps between the spacers and the substrates. In the processes for manufacturing the spacer structure, the pressure plates can be removed without using any release agent or the like, so that a process for removing a release agent can be omitted, and production of dust that is attributable to the release agent can be prevented. Thus, electric discharge can be prevented from being generated by dust in the vacuum envelope. Based on the improvement of the dielectric strength, a high acceleration voltage can be applied between the first and second substrates, so that the obtained SED can exhibit an improved display quality.

The following is a description of an SED according to a second embodiment of this invention.

According to the second embodiment, as shown in FIG. 11, each of first and second spacers 30a and 30b that are set up on a grid 24 is formed of at least two types of materials with different softening temperatures. In this case, each first spacer 30a is composed of a columnar base portion 31b set up on a first surface 24a of the grid 24 and a coating layer 31c that covers the outer periphery and distal end of the base portion. The base portion 31b is formed of a second material with a low softening temperature, while the coating layer 31c is formed of a first material with a softening temperature lower than that of the second material.

Likewise, each second spacer 30b is composed of a columnar base portion 31b set up on a second surface 24b of the grid 24 and a coating layer 31c that covers the outer periphery and distal end of the base portion. The base portion 31b is formed of the second material with a low softening temperature, while the coating layer 31c is formed of the first material with a softening temperature lower than that of the second material.

The first and second surfaces 24a and 24b of the grid 24 and the respective inner surfaces of electron beam apertures 26 are covered by the first material. Materials that contain glass as a dielectric substance are used for the first and second materials.

Other configurations of the second embodiment are the same as those of the foregoing first embodiment, so that like reference numerals are used to designate like portions, and a detailed description thereof is omitted.

In manufacturing a spacer structure 22 according to the second embodiment, as in the case of the foregoing first embodiment, the grid 24 having a given size and upper and lower dies 36a and 36b, each in the form of a rectangular plate having substantially the same size as the grid, are prepared first. After the electron beam apertures 26 are formed in a metal plate of Fe-50% Ni with a plate thickness of 0.12 mm, for the grid 24, the entire metal plate is oxidized. Thereafter, a dielectric film is formed on the grid surface including the respective inner surfaces of the electron beam apertures 26.

The upper die 36a and the lower die 36b are flat plates that are formed of a transparent material that is permeable to ultraviolet rays, such as clear silicone or clear polyethylene terephthalate. The upper die 36a has a flat contact surface 41a to be in contact with the grid 24 and a large number of bottomed spacer forming holes 40a for molding the first spacers 30a. The spacer forming holes 40a individually open in the contact surface 41a of the upper die 36a and are arranged at predetermined intervals. Likewise, the lower die 36b has a flat contact surface 41b and a large number of bottomed spacer forming holes 40b for molding the second spacers 30b. The spacer forming holes 40b individually open in the contact surface 41b of the lower die 36b and are arranged at predetermined intervals.

Subsequently, a second material 46b is loaded as a spacer forming material into the spacer forming holes 40a of the upper die 36a so that the spacer forming holes are filled with the second material. A glass paste that contains at least an ultraviolet-curing binder (organic component) and a glass filler and has a softening temperature of 550° C. and a firing temperature of 550° C.×30 minutes is used as the second material 46b.

Then, ultraviolet (UV) rays are applied to the second material 46b from both sides of the upper die 36a and the lower die 36b to cure it by using an ultraviolet lamp, for example. In this case, the upper die 36a and the lower die 36b are individually formed of an ultraviolet transmitting material. Thus, ultraviolet rays irradiated from the ultraviolet lamp are transmitted through the upper die 36a and the lower die 36b and applied to the second material 46b directly and through the dies. By doing this, the second material 46b is ultraviolet-cured to form the base portions 31b of the spacers

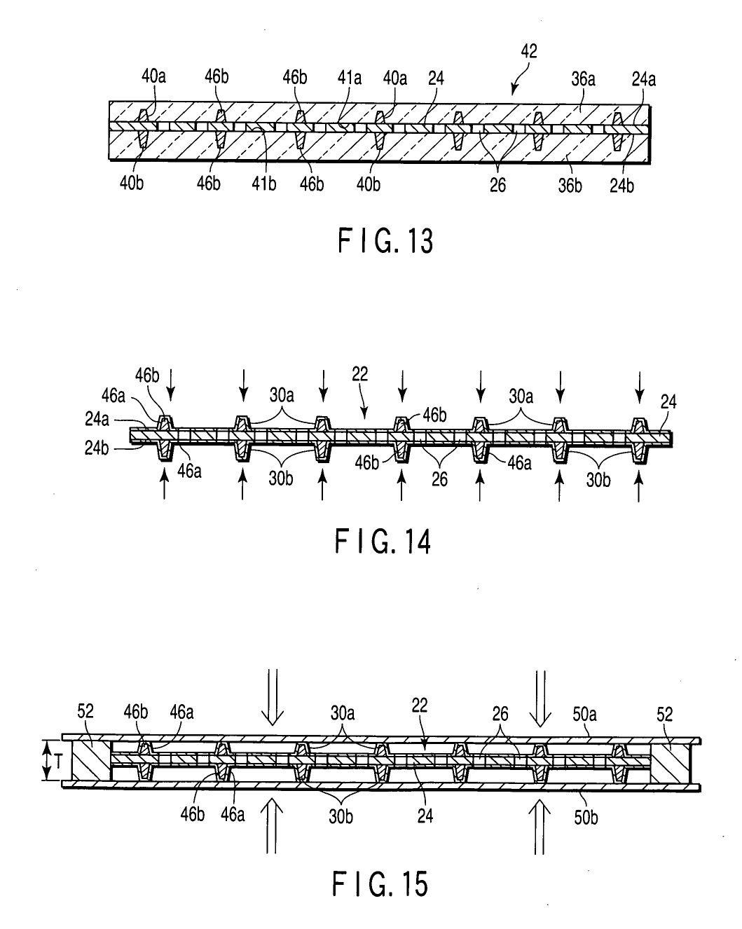

Subsequently, an adhesive is applied to the respective proximal end faces of the base portions 31b, which are exposed on the contact surfaces 41a and 41b of the upper die 36a and the lower die 36b, respectively, and spacer setting positions on the grid 24 by means of a dispenser or by printing. As shown in FIG. 13, thereafter, the upper die 36a is positioned so that the cured base portions 31b individually face regions between the electron beam apertures 26, and the contact surface 41a is brought into close contact with the first surface 24a of the grid 24. Likewise, the lower die 36b is positioned so that the base portions 31b individually face the regions between the electron beam apertures 26, and the contact surface 41b is brought into close contact with the second surface 24b of the grid 24. By doing this, an assembly 42 is formed comprising the grid 24, upper die 36a, and lower die 36b. In the assembly 42, the spacer forming holes 40a of the upper die 36a and the spacer forming holes 40b of the lower die 36b are arranged opposite one another with the grid 24 between them.

The upper die 36a and the lower die 36b are brought into close contact with the grid 24 by pressing the assembly 42 from both surface sides. By doing this, the cured base portions 31b are bonded individually to the first and second surfaces 24a and 24b of the grid 24.

Thereafter, the upper die 36a and the lower die 36b are released from the grid 24 so as to leave the cured base portions 31b on the grid 24. Then, as shown in FIG. 14, a first material 46a with a softening temperature higher than that of the second material 46b is sprayed onto the surface of the grid 24 and the respective outer surfaces of the base portions 31b, whereupon the coating layer 31c of the first material with a thickness of 1 to 50 μm is formed. A glass paste that contains at least a glass filler and has a softening temperature of 585° C. and a firing temperature of 580° C.×30 minutes is used as the first material 46a. The specific gravity and viscosity of each of the glass pastes of the first and second materials 46a and 46b are selected suitably.

After the grid 24 having the base portions 31b and the coating layer 31c thereon is then heat-treated in a heating furnace so that the binder is evaporated from the first and second materials 46a and 46b, it is regularly fired at 580° C. for 30 minutes. By doing this, the first and second spacers 30a and 30b are formed integrally on the first and second surfaces 24a and 24b of the grid 24.

Thereafter, two flat pressure plates 50a and 50b that resemble those of the foregoing first embodiment are prepared, as shown in FIG. 15. Then, the first and second spacers 30a and 30b that are set up on the grid 24 are interposed between the two pressure plates 50a and 50b so that the distal ends of the first spacers 30a are caused to abut against the pressure plate 50a and the distal ends of the second spacers 30b against the pressure plate 50b. Outside the grid 24, a plurality of gap regulating members 52 are arranged between the respective peripheral edge portions of the pressure plates 50a and 50b. A thickness T of each gap regulating member 52 is adjusted highly accurately to a target height of the spacers. The thickness T of the gap regulating member 52 is supposed to be equal to a height obtained by subtracting a compression margin from a height that is equal to the sum of the thickness of the grid 24 and the height of each pair of first and second spacers 30a and 30b. For example, the compression margin and T are supposed to be 0.02 and 1.5 mm, respectively.

Further, the first and second spacers 30a and 30b are heated to a temperature of, e.g., 550° C., which is lower than the softening temperature of the first material 46a and not lower than the softening temperature of the second material 46b, whereby only the base portions 31b that are formed of the second material 46b is softened. In this state, the pressure plates 50a and 50b are pressed toward each other and against the gap regulating members 52. Furthermore, the first and second spacers 30a and 30b are compressed along their height direction from both sides so that they are plastically deformed to a uniform height. The height of each of the first and second spacers 30a and 30b after the compression is controlled by the gap regulating members 52. Thus, the plurality of first spacers 30a are molded to a common height, and at the same time, the plurality of second spacers 30b are molded to a common height.

Subsequently, the first and second spacers 30a and 30b are cooled to be cured again, and thereafter, the pressure plates 50a and 50b are removed. In the pressing process described above, only the second material 46b is softened, and the coating layer 31c that forms the respective distal end portions of the first and second spacers, which abut against the pressure plates 50a and 50b, is not softened. Accordingly, there is no possibility of the spacer end portions and the pressure plates being bonded together, so that the pressure plates 50a and 50b can be easily separated without damaging the first and second spacers.

By the processes described above, the spacer structure 22 is obtained having the first and second spacers 30a and 30b built-in on the grid 24. The height differences between the adjacent first spacers 30a are restricted within 5 μm, and the height variation of all the first spacers is restricted within 0.1 mm. Further, the height differences between the adjacent second spacers 30b are restricted within 5 μm, and the height variation of all the second spacers is restricted within 0.1 mm. In a spacer structure that is not subjected to the aforesaid pressing process, the standard deviation of the heights of the first and second spacers is 0.008. In the present embodiment, however, the standard deviation is 0.001, which indicates a considerable reduction in the spacer height variation.

Thereafter, the SED is manufactured having the spacer structure 22 by the same method of the first embodiment.

The SED according to the second embodiment constructed in this manner and an SED having dispensed with the spacer height variation control were prepared, and a discharge test was conducted for each of them. When the SED not controlled for height variation was held at an acceleration voltage of 10 kV for one hour, electric discharge occurred about 10 times. When this SED was held for 10 hours, electric discharge occurred about 25 times. For the SED according to the present embodiment, on the other hand, no electric discharge occurred under the same conditions.

Thus, also in the second embodiment, the same function and effect of the foregoing first embodiment can be obtained, and there may be obtained an SED with high dielectric strength and improved reliability and display quality.

The following is a description of an SED according to a third embodiment of this invention.

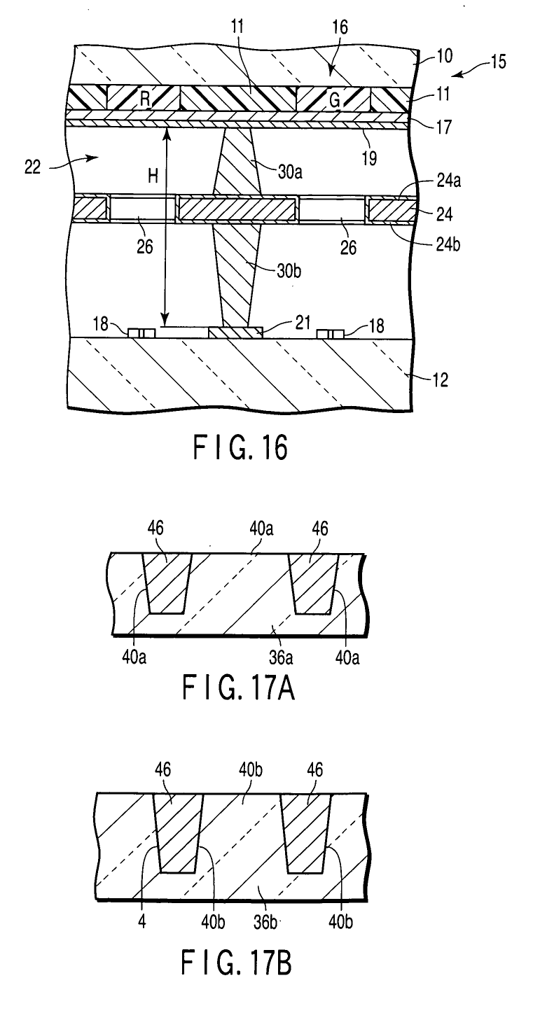

According to the third embodiment, as shown in FIG. 16, each of first and second spacers 30a and 30b that are set up on a grid 24 is formed of one type of material. In this case, a material that contains glass as a dielectric substance is used as a spacer forming material. Other configurations of the third embodiment are the same as those of the foregoing first embodiment, so that like reference numerals are used to designate like portions, and a detailed description thereof is omitted.

In manufacturing a spacer structure 22 according to the third embodiment, as in the case of the foregoing second embodiment, the grid 24 having a given size and upper and lower dies 36a and 36b, each in the form of a rectangular plate having substantially the same size as the grid, are prepared. Subsequently, as shown in FIGS. 17A and 17B, a spacer forming material 46 is loaded into spacer forming holes 40a of the upper die 36a and spacer forming holes 40b of the lower die 26b to fill the spacer forming holes. A glass paste that contains at least an ultraviolet-curing binder (organic component) and a glass filler and has a softening temperature of 550° C. and a firing temperature of 550° C.×30 minutes is used as the spacer forming material.

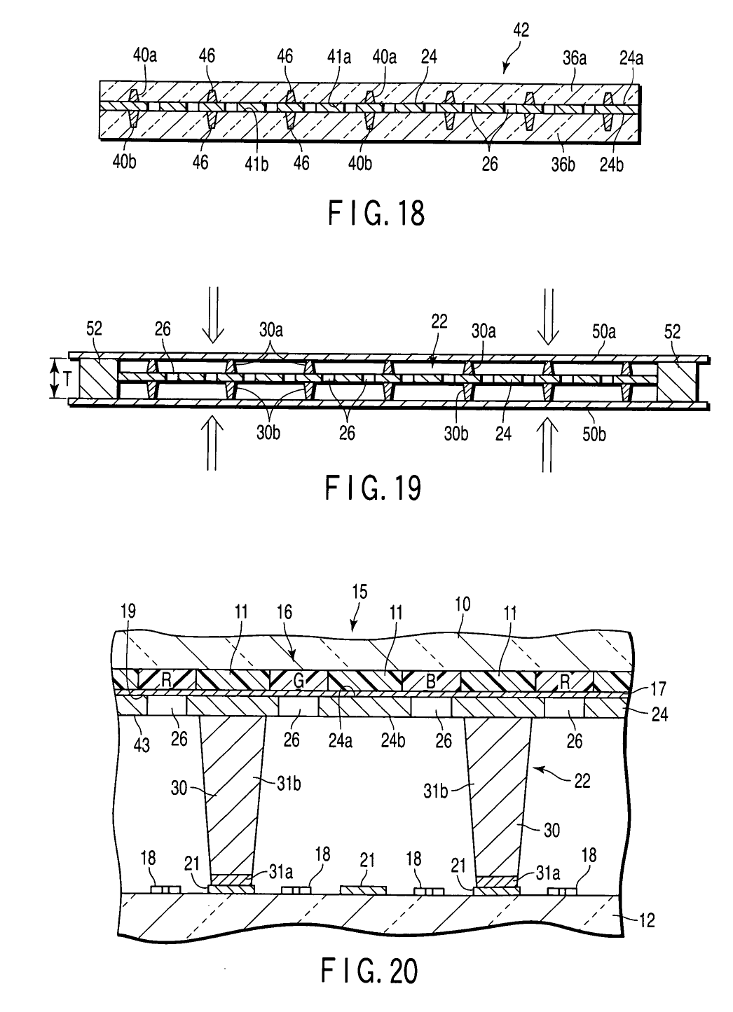

Then, ultraviolet (UV) rays are applied to the spacer forming material 46 from both sides of the upper die 36a and the lower die 36b to cure it by using an ultraviolet lamp. Subsequently, an adhesive is applied to the respective proximal end faces of the spacer forming material 46, which are exposed on contact surfaces 41a and 41b of the upper die 36a and the lower die 36b, respectively, and spacer setting positions on the grid 24 by means of a dispenser or by printing. As shown in FIG. 18, thereafter, the upper die 36a is positioned so that the cured spacer forming material 46 faces regions between electron beam apertures 26, and the contact surface 41a is brought into close contact with a first surface 24a of the grid 24. Likewise, the lower die 36b is positioned so that base portions 31b individually face the regions between the electron beam apertures 26, and the contact surface 41b is brought into close contact with a second surface 24b of the grid 24. By doing this, an assembly 42 is formed comprising the grid 24, upper die 36a, and lower die 36b. This assembly 42 is pressed from both sides to bring the upper die 36a and the lower die 36b into close contact with the grid 24. By doing this, the cured spacer forming material 46 is bonded to the first and second surfaces 24a and 24b of the grid 24.

Then, the upper die 36a and the lower die 36b are released from the grid 24 so as to leave the cured spacer forming material 46 on the grid 24. After the grid 24 having the spacer forming material 46 thereon is heat-treated in a heating furnace so that the binder is evaporated from the spacer forming material 46, it is regularly fired at 550° C. for 30 minutes. By doing this, the first and second spacers 30a and 30b are formed integrally on the first and second surfaces 24a and 24b of the grid 24.

Thereafter, two flat pressure plates 50a and 50b that resemble those of the foregoing first embodiment are prepared, as shown in FIG. 19. As a dielectric remover, a water solution of silicon oxide powder with a particle size of about 1 μm, for example, is applied to the respective surfaces of the pressure plates 50a and 50b by spraying. Then, the first and second spacers 30a and 30b that are set up on the grid 24 are interposed between the two pressure plates 50a and 50b so that the distal ends of the first spacers 30a are caused to abut against the pressure plate 50a and the distal ends of the second spacers 30b against the pressure plate 50b. Outside the grid 24, a plurality of gap regulating members 52 are arranged between the respective peripheral edge portions of the pressure plates 50a and 50b. A thickness T of each gap regulating member 52 is supposed to be equal to a height obtained by subtracting a compression margin from a height that is equal to the sum of the thickness of the grid 24 and the height of each pair of first and second spacers 30a and 30b. For example, the compression margin and T are supposed to be 0.02 and 1.5 mm, respectively.

Further, the first and second spacers 30a and 30b are heated to 550° C., whereby the spacer forming material 46 is softened. In this state, the pressure plates 50a and 50b are pressed toward each other and against the gap regulating members 52. Furthermore, the first and second spacers 30a and 30b are compressed along their height direction from both sides so that they are plastically deformed to a uniform height. The height of each of the first and second spacers 30a and 30b after the compression is controlled by the gap regulating members 52. Thus, the plurality of first spacers 30a are molded to a common height, and at the same time, the plurality of second spacers 30b are molded to a common height.

Subsequently, the first and second spacers 30a and 30b are cooled to be cured again, and thereafter, the pressure plates 50a and 50b are removed. Since the remover is applied to the pressure plates 50a and 50b, as this is done, the distal end portions of the spacers and the pressure plates can never be bonded together, so that the pressure plates 50a and 50b can be easily separated without damaging the first and second spacers. After the pressure plates 50a and 50b are separated, the remover that adheres to the distal ends of the first and second spacers 30a and 30b is removed by using sandpaper or the like.

By the processes described above, the spacer structure 22 is obtained having the first and second spacers 30a and 30b built-in on the grid 24. The height differences between the adjacent first spacers 30a are restricted within 5 μm, and the height variation of all the first spacers is restricted within 0.1 mm. Further, the height differences between the adjacent second spacers 30b are restricted within 5 μm, and the height variation of all the second spacers is restricted within 0.1 mm. In a spacer structure that is not subjected to the aforesaid pressing process, the standard deviation of the heights of the first and second spacers is 0.008. In the present embodiment, however, the standard deviation is 0.002, which indicates a considerable reduction in the spacer height variation.

Thereafter, the SED is manufactured having the spacer structure 22 by the same method of the first embodiment.

The SED according to the third embodiment constructed in this manner and an SED having dispensed with the spacer height variation control were prepared, and a discharge test was conducted for each of them. When the SED not controlled for height variation was held at an acceleration voltage of 10 kV for one hour, electric discharge occurred about 10 times. When this SED was held for 10 hours, electric discharge occurred about 25 times. For the SED according to the present embodiment, on the other hand, electric discharge occurred zero time and three times under these individual conditions, thus indicating a considerable improvement.

Thus, also in the third embodiment, the height variation of the first spacers 30a and the second spacers 30b can be eliminated, and the gaps between the first substrate and the first spacers and between the second substrate and the second spacers can be reduced considerably. Accordingly, there may be obtained an SED with high dielectric strength and improved reliability in which electric discharge can be restrained from being caused by the gaps between the spacers and the substrates. If the remover is used, it may be adversely affected by dust. Since a favorable effect of the reduction of the spacer height variation surpasses the adverse effect, however, the dielectric strength can be eventually improved. If a dielectric material is used as the remover, moreover, electric discharge cannot be easily caused by a residue of the remover.

Although the spacer structure 22 integrally comprises the first and second spacers and the grid according to the embodiment described above, the second spacers 30b may alternatively be formed on the second substrate 12. Further, the spacer structure may be provided with only the grid and the second spacers, and the grid may be configured to be in direct contact with the first substrate.

According to an SED according to a fourth embodiment of this invention, as shown in FIG. 20, a spacer structure 22 comprises a supporting substrate 24, which is formed of a rectangular metal plate and functions as a grid, and a large number of columnar spacers 30 that are set up integrally on only one surface of the supporting substrate. The supporting substrate 24 has a first surface 24a opposed to the inner surface of a first substrate 10 and a second surface 24b opposed to the inner surface of a second substrate 12, and is located parallel to these substrates. A large number of electron beam apertures 26 are formed in the supporting substrate 24 by etching or the like. The electron beam apertures 26 are arranged opposite electron emitting elements 18, individually, and electron beams emitted from the electron emitting elements are transmitted through them.

The first and second surfaces 24a and 24b of the supporting substrate 24 and the respective inner wall surfaces of the electron beam apertures 26 are covered by a high-resistance film as a dielectric layer, which consists mainly of glass, ceramics, etc. The first surface 24a of the supporting substrate 24 is provided in surface contact with the inner surface of the first substrate 10 with a getter film 19, a metal back 17, and a phosphor screen 16 between them. The electron beam apertures 26 in the supporting substrate 24 individually face phosphor layers R, G and B of the phosphor screen 16. Thus, electron emitting elements 18 face their corresponding phosphor layers through the electron beam apertures 26, individually.

A plurality of columnar spacers 30 are set up integrally on the second surface 24b of the supporting substrate 24. An extended end of each spacer 30 abuts against the inner surface of the second substrate 12 or a wire 21 on the inner surface of the second substrate 12 in this case. Each of the spacers 30 is tapered so that its diameter is reduced from the side of the grid 24 toward its extended end. For example, the spacer 30 has a height of about 1.4 mm. A cross section of the spacer 30 that extends along a direction parallel to the grid surface is substantially elliptic. Height differences between the adjacent spacers 30 are restricted within 5 μm, and height variation of all the spacers is restricted within 0.1 mm. Further, height differences between the adjacent second spacers 30b are restricted within 5 μm, and height variation of all the second spacers is restricted within 0.1 mm.

Each of the spacers 30 is formed of at least two types of materials with different softening temperatures. In this case, a tip portion 31a of each spacer 30 that abuts against the second substrate 12 is formed of a first material with a high softening temperature, while the other portion or a base portion 31b thereof that extends from the supporting substrate 24 to the tip portion is formed of a second material with a softening temperature lower than that of the first material. Materials that contain glass as a dielectric substance are used for the first and second materials.

In the spacer structure 22 constructed in this manner, the grid 24 is in surface contact with the first substrate 10, and the extended end of each spacer 30 abuts against the inner surface of the second substrate 12, thereby supporting an atmospheric load that acts on these substrates and keeping a space between the substrates at a given value.

Other configurations of the fourth embodiment are the same as those of the foregoing first embodiment, so that like reference numerals are used to designate like portions, and a detailed description thereof is omitted. The SED according to the fourth embodiment and its spacer structure can be manufactured by a manufacturing method similar to the manufacturing methods according to the foregoing embodiments. The same function and effect of the foregoing first embodiment can be also obtained according to the fourth embodiment.

The present invention is not limited directly to the embodiment described above, and its components may be embodied in modified forms without departing from the spirit of the invention. Further, various inventions may be made by suitably combining a plurality of components described in connection with the foregoing embodiment. For example, some of the components according to the foregoing embodiment may be omitted. Furthermore, components according to different embodiments may be combined as required.

The diameter and height of the spacers and the dimensions, materials, etc. of the other components are not limited to the foregoing embodiments, but may be suitably selected as required. The spacer forming material loading conditions may be variously selected as required. Further, this invention is not limited to image display devices that use surface-conduction electron emitting elements as electron sources, but may alternatively be applied to ones that use other electron sources, such as the field-emission type, carbon nanotubes, etc.

What is claimed is:

1. An image display device comprising:
a first substrate having an image display screen formed thereon;
a second substrate located opposite the first substrate with a predetermined gap therebetween and provided with a plurality of electron emitting sources which excite the image display screen; and
a plurality of spacers which are individually formed of dielectric materials, are provided between the first substrate and the second substrate, individually have end portions which abut against at least one of the first substrate and the second substrate, and support an atmospheric load which acts on the first and second substrates, each of the spacers being formed of at least two types of materials with different softening temperatures, the end portions which abut against at least one of the first substrate and the second substrate being formed of a material with a high softening temperature.

2. An image display device comprising:
a first substrate having an image display screen formed thereon;
a second substrate located opposite the first substrate with a predetermined gap therebetween and provided with a plurality of electron emitting sources which excite the image display screen;
a plate-shaped supporting substrate having a plurality of electron beam apertures opposed individually to the electron emitting elements and provided opposite the first and second substrates and between the first and second substrates; and
a plurality of spacers which are individually formed of dielectric materials, are provided on the supporting substrate, individually have end portions which abut against at least one of the first substrate and the second substrate, and support an atmospheric load which acts on the first and second substrates, each of the spacers being formed of at least two types of materials with different softening temperatures, the end portions which abut against at least one of the first substrate and the second substrate being formed of a material with a high softening temperature.

3. The image display device according to claim 2, wherein the supporting substrate has a first surface opposed to the first substrate and a second surface opposed to the second substrate, and the spacers include a plurality of first spacers set up on the first surface and individually having end portions which abut against the first surface and a plurality of second spacers set up on the second surface and individually having end portions which abut against the second surface.

4. The image display device according to claim 2, wherein the supporting substrate has a first surface in contact with the first substrate and a second surface opposed to the second substrate, and the spacers are set up on the second surface and individually have end portions in contact with the second substrate.

5. The image display device according to claim 1, wherein each of the spacers has a columnar shape.

6. The image display device according to claim 5, wherein each of the spacers is formed of a first material and a second material with a softening temperature lower than that of the first material, and each of the spacers has a columnar base portion formed of the second material and a coating layer which is formed of the first material and covers an outer surface of the base portion.

7. The image display device according to claim 1, wherein each of the spacers has a columnar shape, and height differences between the adjacent spacers and height variation of all the spacers are restricted within 5 μm and 0.1 mm, respectively, the height of each spacer being a length of the spacer in a direction perpendicular to the first and second substrates.

8. A method of manufacturing an image display device which comprises a first substrate having an image display screen formed thereon, a second substrate located opposite the first substrate with a predetermined gap therebetween and provided with a plurality of electron emitting sources which excite the image display screen, and a plurality of spacers which are individually formed of dielectric materials, are provided between the first substrate and the second substrate, individually have end portions which abut against at least one of the first substrate and the second substrate, and support an atmospheric load which acts on the first and second substrates, the method comprising:
preparing a molding die having a plurality of bottomed spacer forming holes;
filling a bottom portion of each spacer forming hole of the molding die with an amount of a first material which contains glass and has a high softening temperature, the amount being smaller than the size of the spacer forming hole;
filling each spacer forming hole of the molding die, filled with the first material, with a second material which contains glass and has a softening temperature lower than the softening temperature of the first material;
curing and then releasing the loaded first and second materials from the molding die;
firing the released first and second materials to form the plurality of spacers; and
pressing the plurality of fired spacers in a height direction thereof to mold the spacers to a common height by means of a pressure plate which engages respective distal ends of the plurality of spacers when the plurality of spacers are heated to a temperature lower than the softening temperature of the first material and not lower than the softening temperature of the second material.

9. The method of manufacturing an image display device according to claim 8, wherein an ultraviolet-curing dielectric glass is used for the first and second materials, and the first and second materials are cured by being irradiated with ultraviolet rays.

10. The method of manufacturing an image display device according to claim 8, wherein the spacers are pressed in a manner such that the spacers and a gap regulating member of a predetermined thickness are located between two pressure plates and the spacer members are held between the two pressure plates.

11. A method of manufacturing an image display device which comprises a first substrate having an image display screen formed thereon, a second substrate located opposite the first substrate with a predetermined gap therebetween and provided with a plurality of electron emitting sources which excite the image display screen, a plate-shaped supporting substrate having a plurality of electron beam apertures opposed individually to the electron emitting elements and provided opposite the first and second substrates and between the first and second substrates, and a plurality of spacers which are individually formed of dielectric materials, are provided on the supporting substrate, individually have end portions which abut against the first substrate and/or the second substrate, and support an atmospheric load which acts on the first and second substrates, the method comprising:
preparing a plate-shaped supporting substrate having a plurality of electron beam apertures and a molding die having a plurality of bottomed spacer forming holes;
filling a bottom portion of each spacer forming hole of the molding die with an amount of a first material which contains glass and has a high softening temperature, the amount being smaller than the size of the spacer forming hole;
filling each spacer forming hole of the molding die, filled with the first forming material, with a second material which contains glass and has a softening temperature lower than the softening temperature of the first material;
curing and then releasing the loaded first and second materials from the molding die and locating the materials on the supporting substrate with the second material side bonded to the supporting substrate;
firing the first and second materials on the supporting substrate to form the plurality of spacers; and
pressing the plurality of fired spacers in a height direction thereof to mold the spacers to a common height by means of a pressure plate which engages respective distal ends of the plurality of spacers when the plurality of spacers are heated to a temperature lower than the softening temperature of the first material and not lower than the softening temperature of the second material.

12. A method of manufacturing an image display device which comprises a first substrate having an image display screen formed thereon, a second substrate located opposite the first substrate with a predetermined gap therebetween and provided with a plurality of electron emitting sources which excite the image display screen, a plate-shaped supporting substrate having a plurality of electron beam apertures opposed individually to the electron emitting elements and provided opposite the first and second substrates and between the first and second substrates, and a plurality of spacers which are individually formed of dielectric materials, are provided on the supporting substrate, individually have end portions which abut against the first substrate and/or the second substrate, and support an atmospheric load which acts on the first and second substrates, the method comprising:
preparing a plate-shaped supporting substrate having a plurality of electron beam apertures and a molding die having a plurality of bottomed spacer forming holes;
filling each spacer forming hole of the molding die with a second material which contains glass and has a low softening temperature;
curing and then releasing the loaded second material from the molding die and locating the material on the supporting substrate in a manner such that the material is bonded to the supporting substrate;
covering an outer surface of a base portion with a first material which contains glass and has a softening temperature higher than the softening temperature of the second material and firing the first material to form the plurality of spacers; and
pressing the plurality of spacers in a height direction thereof to mold the spacers to a common height by means of a pressure plate which engages respective distal ends of the plurality of spacers when the spacers are heated to a temperature lower than the softening temperature of the first material and not lower than the softening temperature of the second material.

13. A method of manufacturing an image display device which comprises a first substrate having an image display screen formed thereon, a second substrate located opposite the first substrate with a predetermined gap therebetween and provided with a plurality of electron emitting sources which excite the image display screen, a plate-shaped supporting substrate having a plurality of electron beam apertures opposed individually to the electron emitting elements and provided opposite the first and second substrates and between the first and second substrates, and a plurality of spacers which are individually formed of dielectric materials, are provided on the supporting substrate, individually have end portions which abut against the first substrate and/or the second substrate, and support an atmospheric load which acts on the first and second substrates, the method comprising:
preparing a plate-shaped supporting substrate having a plurality of electron beam apertures; forming a plurality of spacers of a spacer forming material which contains glass on the supporting substrate; and
causing a pressure plate coated with a dielectric remover to engage respective distal ends of the plurality of spacers when the spacers are heated to a temperature not lower than the softening temperature of the spacer forming material and pressing the plurality of spacers in a height direction thereof to mold the spacers to a common height by means of the pressure plate.
